(19) United States
(12) Patent Application Publication
(10) Pub. No.: US 2025/0157795 A1
(43) Pub. Date: May 15, 2025

(54) ELECTROSTATIC CHUCK, METHOD OF MANUFACTURING ELECTROSTATIC CHUCK, AND PLASMA PROCESSING APPARATUS

(71) Applicant: SEMES CO., LTD., Cheonan-si (KR)

(72) Inventors: Jun Seok PARK, Cheonan-si (KR); Jong Joon JEON, Cheonan-si (KR); Yong Jae KIM, Cheonan-si (KR); Chul Ho JUNG, Cheonan-si (KR); Ja Myung GU, Cheonan-si (KR)

(73) Assignee: SEMES CO., LTD., Cheonan-si (KR)

(21) Appl. No.: 18/939,613

(22) Filed: Nov. 7, 2024

(30) Foreign Application Priority Data
Nov. 9, 2023 (KR) 10-2023-0154334

(51) Int. Cl. H01J 37/32; H01J 9/30

(52) U.S. Cl. CPC H01J 37/32715; H01J 9/30; H01J 37/32807; H01J 2237/2007; H01J 2237/20235

(57) ABSTRACT

Disclosed are an electrostatic chuck capable of preventing deformation of a bonding layer and damage to a lift pin, a method of manufacturing the electrostatic chuck, and a plasma processing apparatus. The electrostatic chuck configured to support a substrate and to receive a lift pin so that the lift pin is ascendable and descendable therein includes at least one pin hole formed vertically therethrough to allow the lift pin to ascend and descend along the pin hole, a ceramic puck configured to allow the substrate to be seated thereon, a base plate configured to support the ceramic puck, a bonding layer configured to bond the ceramic puck to the base plate, and an insulating pipe mounted on an inner side wall of the pin hole. The insulating pipe includes an upper insulating pipe bonded to the ceramic puck and a lower insulating pipe adhered to the base plate.

### CROSS REFERENCE TO RELATED APPLICATION

The present application claims priority to Korean Patent Application No. 10-2023-0154334, filed Nov. 9, 2023, the entire contents of which is incorporated by reference herein for all purposes.

### BACKGROUND

### Field of the Disclosure

The present disclosure relates to an electrostatic chuck configured to support a substrate, a method of manufacturing the electrostatic chuck, and a plasma processing apparatus including the electrostatic chuck.

### Description of the Related Art

A semiconductor manufacturing process is a process for manufacturing a semiconductor device on a substrate (e.g., wafer), and includes, for example, exposure, deposition, etching, ion implantation, and cleaning. In order to perform each manufacturing process, semiconductor manufacturing equipment that performs each process is provided in a clean room of a semiconductor manufacturing plant, and each process is performed on a substrate loaded in the semiconductor manufacturing equipment.

Processes using plasma, for example, etching and deposition, are widely used in the semiconductor manufacturing process. A plasma processing process is performed by loading a substrate at a lower portion in a plasma processing space and applying voltage through electrodes located above and below the substrate while supplying fluid for plasma processing.

When loading a substrate to be plasma-processed on an electrostatic chuck or unloading the substrate from the electrostatic chuck after completion of processing, a transfer robot puts down or supports the substrate. To this end, a lift pin configured to raise or lower the substrate is provided in the electrostatic chuck. The lift pin ascends or descends through a pin hole formed in the electrostatic chuck, thereby raising or lowering the substrate. A bush (insulating pipe) configured to surround the lift pin is located in the pin hole into which the lift pin is inserted.

A conventional insulating pipe is inserted into the pin hole in a state of being adhered to a bonding layer that bonds a ceramic puck to a base plate. However, the bonding layer may be deformed due to plasma, and the insulating pipe may be warped due to a difference in heat strain between the ceramic puck and the base plate in the electrostatic chuck, which may cause damage to the lift pin.

### SUMMARY

Therefore, the present disclosure has been made in view of the above problems, and it is an object of the present disclosure to provide an electrostatic chuck capable of preventing deformation of a bonding layer and damage to a lift pin, a method of manufacturing the electrostatic chuck, and a plasma processing apparatus.

In accordance with an aspect of the present disclosure, the above and other objects can be accomplished by the provision of an electrostatic chuck configured to support a substrate and to receive a lift pin so that the lift pin is ascendable and descendable therein, the electrostatic chuck including at least one pin hole formed vertically therethrough to allow the lift pin to ascend and descend along the pin hole, a ceramic puck configured to allow the substrate to be seated thereon, a base plate configured to support the ceramic puck, a bonding layer configured to bond the ceramic puck to the base plate, and an insulating pipe mounted on an inner side wall of the pin hole, wherein the insulating pipe includes an upper insulating pipe bonded to the ceramic puck and a lower insulating pipe adhered to the base plate.

In the embodiment of the present disclosure, the upper insulating pipe may include a bonding portion brazed to an inner side wall of the pin hole in the ceramic puck.

In the embodiment of the present disclosure, the upper insulating pipe may include a protruding portion protruding outward from a lower side of the bonding portion so as to be attached to the bonding layer.

In the embodiment of the present disclosure, the upper insulating pipe may include a body portion extending downward from a lower side of the protruding portion and having a smaller diameter than the protruding portion.

In the embodiment of the present disclosure, the body portion may be attached to the base plate by means of a bonding material.

In the embodiment of the present disclosure, the bonding material may be formed on an outer side of the body portion around a coupling portion between the upper insulating pipe and the lower insulating pipe.

In the embodiment of the present disclosure, the body portion and the base plate may be disposed with a gap therebetween.

In the embodiment of the present disclosure, the lower insulating pipe may be adhered to the base plate and the upper insulating pipe in a state of being inserted into a recess formed in the base plate.

In accordance with another aspect of the present disclosure, there is provided a method of manufacturing an electrostatic chuck configured to support a substrate and to receive a lift pin so that the lift pin is ascendable and descendable therein and including at least one pin hole formed vertically therethrough to allow the lift pin to ascend and descend along the pin hole, the method including forming a bonding layer on an upper surface of a base plate, bonding an upper insulating pipe to an inner side wall of the pin hole in a ceramic puck configured to allow the substrate to be seated thereon, adhering the ceramic puck to an upper side of the bonding layer so that the upper insulating pipe is inserted into the pin hole in the base plate, and adhering a lower insulating pipe to a lower side of the upper insulating pipe and the base plate.

In accordance with a further aspect of the present disclosure, there is provided a plasma processing apparatus including a chamber including a plasma processing space for a substrate defined therein, an electrostatic chuck configured to support the substrate and to receive a lift pin so that the lift pin is ascendable and descendable therein, an upper electrode configured to generate plasma in the plasma processing space, a window configured to isolate the upper electrode from the plasma processing space, a power supply configured to supply power to the upper electrode, a gas supply member configured to supply a process gas to the plasma processing space, and a gas source configured to supply the process gas to the gas supply member, wherein the electrostatic chuck includes at least one pin hole formed vertically therethrough to allow the lift pin to ascend and descend along the pin hole, a ceramic puck configured to allow the substrate to be seated thereon, a base plate configured to support the ceramic puck, a bonding layer configured to bond the ceramic puck to the base plate, and an insulating pipe mounted on an inner side wall of the pin hole, the insulating pipe includes an upper insulating pipe bonded to the ceramic puck and a lower insulating pipe adhered to the base plate, and the upper insulating pipe includes a bonding portion brazed to an inner side wall of the pin hole in the ceramic puck, a protruding portion protruding outward from a lower side of the bonding portion so as to be attached to the bonding layer, and a body portion extending downward from a lower side of the protruding portion and having a smaller diameter than the protruding portion.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a view schematically showing the structure of a plasma processing apparatus according to the present disclosure;

FIG. 2 is a view showing a coupling structure of an insulating pipe in an electrostatic chuck according to a comparative example;

FIG. 3 is a view showing a coupling structure of an insulating pipe in an electrostatic chuck according to the present disclosure;

FIG. 4 is a flowchart showing a method of manufacturing the electrostatic chuck according to the present disclosure; and

FIGS. 5 to 8 are views showing a coupling process of the electrostatic chuck according to the present disclosure.

### DETAILED DESCRIPTION

Hereinafter, embodiments of the present disclosure will be described in detail with reference to the accompanying drawings so that those skilled in the art can easily carry out the embodiments. The present disclosure may, however, be embodied in many different forms, and should not be construed as being limited to the embodiments set forth herein.

Parts irrelevant to description of the present disclosure will be omitted to clearly describe the present disclosure, and the same or similar constituent elements will be denoted by the same reference numerals throughout the specification.

In addition, constituent elements having the same configurations in several embodiments will be assigned with the same reference numerals and described only in the representative embodiment, and only constituent elements different from those of the representative embodiment will be described in the other embodiments.

Throughout the specification, when a constituent element is said to be “connected”, “coupled”, or “joined” to another constituent element, the constituent element and the other constituent element may be “directly connected”, “directly coupled”, or “directly joined” to each other, or may be “indirectly connected”, “indirectly coupled”, or “indirectly joined” to each other with one or more intervening elements interposed therebetween. In addition, throughout the specification, when a constituent element is referred to as “comprising”, “including”, or “having” another constituent element, the constituent element should not be understood as excluding other elements, so long as there is no special conflicting description, and the constituent element may include at least one other element.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Hereinafter, an electrostatic chuck 20, a plasma processing method, and a plasma processing apparatus 1 will be described. The plasma processing apparatus 1 is equipment for performing plasma processing (e.g., dry etching) on a substrate W. When the substrate W is loaded in the plasma processing apparatus 1, high-frequency power is applied to an upper electrode and a lower electrode to generate an electromagnetic field, and a process gas supplied to the substrate W transitions to a plasma state due to the electromagnetic field, and reacts with a specific material of the substrate W. The substrate W having undergone plasma processing for a certain period of time is discharged to the outside of the plasma processing apparatus 1, and subsequent processing processes are performed.

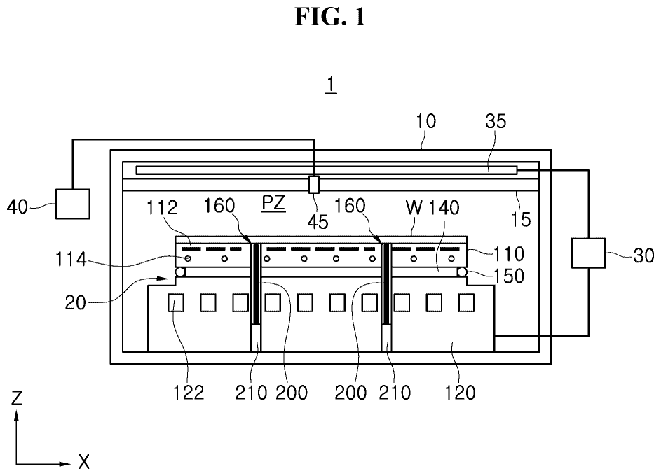

FIG. 1 is a view schematically showing the structure of a plasma processing apparatus 1 according to the present disclosure. The plasma processing apparatus 1 according to the present disclosure includes a chamber 10 including a plasma processing space PZ for a substrate W defined therein, an electrostatic chuck 20 configured to support the substrate W, an upper electrode 35 configured to generate plasma in the plasma processing space PZ, a window 15 configured to isolate the upper electrode 35 from the plasma processing space PZ, a power supply 30 configured to supply power to the upper electrode 35, a gas supply member 45 configured to supply a process gas to the plasma processing space PZ, and a gas source 40 configured to supply the process gas to the gas supply member 45. In addition, although not specifically shown in the drawings, the plasma processing apparatus 1 may include an opening/closing door configured to expose or shield the interior of the chamber 10 to or from the outside space and a baffle configured to discharge by-products generated by plasma processing and gas to the outside.

The chamber 10 includes the plasma processing space PZ for the substrate W defined therein, and components for plasma processing are mounted in the chamber 10. The window 15, the upper electrode 35, and the gas supply member 45 are disposed at an upper portion in the chamber 10, and the electrostatic chuck 20 is disposed at a lower portion in the chamber 10.

The window 15 isolates an upper space in which the upper electrode 35 is located from the plasma processing space PZ. The window 15 is formed to cover the upper side of the chamber 10 in order to seal the inner space in the chamber 10. The window 15 may be formed in a plate shape (e.g., disc shape), and may be made of an insulative material (e.g., alumina (Al₂O₃)).

The electrostatic chuck 20 is disposed at a lower portion in the chamber 10, and supports the substrate W using electrostatic force. The electrostatic chuck 20 may be provided therein with an electrode 112 to strongly attract the substrate W to the electrostatic chuck 20 with electrostatic force. The electrostatic chuck 20 may function as a lower electrode for generation of plasma.

The electrostatic chuck 20 includes a ceramic puck 110 configured to allow the substrate W to be plasma-processed to be seated thereon and including a heater 114 mounted therein, a base plate 120 configured to support a lower side of the ceramic puck 110 and including a cooling path 122 formed therein to allow cooling fluid to flow therethrough, a bonding layer 140 configured to bond the ceramic puck 110 to the base plate 120, and an insulating pipe 300 mounted on an inner side wall of a pin hole 160.

The ceramic puck 110 is a structure configured to support the substrate W from below, and is provided therein with the electrode 112 and the heater 114. The ceramic puck 110 may be made of a ceramic material (e.g., quartz).

The base plate 120 is formed in a disc shape made of metal (e.g., Al). The base plate 120 may include a lower region having a predetermined diameter and an upper region having a smaller diameter than the lower region. A cooling path 122 may be formed in the lower region of the base plate 120. The upper region of the base plate 120 may be coupled to the ceramic puck 110. That is, the base plate 120 may have a shape in which the lower region protrudes. Although not shown in the drawings, an edge ring (not shown) for control of plasma on an edge portion of the substrate W may be provided on the protruding portion of the base plate 120.

A coating layer made of alumina (Al₂O₃) may be formed on an outer surface of the base plate 120. The coating layer prevents the base plate 120 made of metal (e.g., Al) from being exposed to the external environment, particularly, plasma.

A bonding layer 140 is formed between the ceramic puck 110 and the base plate 120 to adhere the ceramic puck 110 to the base plate 120. The base plate 120 and the ceramic puck 110 may be adhered to each other by means of the bonding layer 140 made of an adhesive material. A ring-shaped sealing member 150 may be provided between the ceramic puck 110 and the base plate 120 so as to surround an outer side of the bonding layer 140. The sealing member 150 seals the bonding layer 140, thereby preventing the bonding layer 140 from being exposed to the external environment, particularly, plasma.

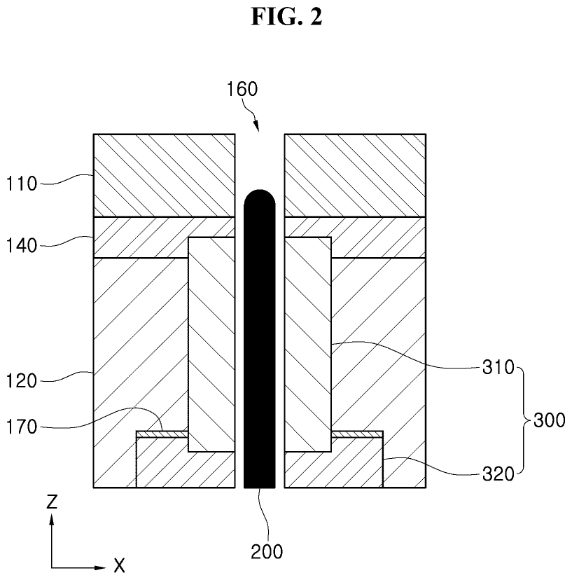

A pin hole 160 is formed in the electrostatic chuck 20 as a movement path of a lift pin 200 for raising or lowering the substrate W. The pin hole 160 is formed so as to penetrate the electrostatic chuck 20 in a vertical direction Z. The lift pin 200 ascends or descends along the pin hole 160, thereby raising or lowering the substrate W. An elevation driving unit 210 configured to raise or lower the lift pin 200 is provided under the lift pin 200. The elevation driving unit 210 may be composed of a cylinder or a linear motor. For example, three lift pins 200 may be provided. An insulating pipe 300 may be inserted into the pin hole 160 in order to insulate the pin hole 160. A coupling structure of the insulating pipe 300 and the electrostatic chuck 20 will be described in detail later with reference to FIGS. 2 to 8.

The power supply 30 applies power to the upper electrode and to the lower electrode provided at the electrostatic chuck 20. The power supply 30 may be configured to control the characteristics of plasma. The power supply 30 may be configured to control, for example, ion bombardment energy. Although the power supply 30 is illustrated in FIG. 1 as being connected both to the upper electrode 35 and to the electrostatic chuck 20, the disclosure is not limited thereto. An upper power supply connected to the upper electrode 35 and a lower power supply connected to the electrostatic chuck 20 may be provided separately from each other. The upper power supply may include a plurality of power supplies, and the lower power supply may include a plurality of power supplies. In a case in which the upper power supply is provided in plural, a matching network electrically connected to the plurality of upper power supplies may be provided at the plasma processing apparatus 1. The matching network may match different magnitudes of frequency power input from the respective upper power supplies and the lower power supply, and may apply the matched frequency power to the upper electrode 35 and the electrostatic chuck 20. In addition, impedance matching circuits (not shown) may be provided on transmission lines connecting the upper power supply and the lower power supply to the upper electrode 35 and the electrostatic chuck 20 for the purpose of impedance matching.

The upper electrode 35 generates plasma from gas remaining in the plasma processing space PZ. Here, the plasma processing space PZ refers to a space located above the electrostatic chuck 20 in the inner space in the chamber 10. The upper electrode 35 may generate plasma in accordance with an inductively coupled plasma method or a capacitively coupled plasma method. The upper electrode 35 may generate an electromagnetic field from the power supplied from the power supply 30. A matching circuit for impedance matching may be provided between the upper electrode 35 and the power supply 30.

The gas source 40 supplies an etching gas as a process gas used to process the substrate W. The gas source 40 may supply a gas containing a fluorine component (e.g., gas containing SF₆ or CF₄) to the gas supply member 45 as an etching gas.

The gas supply member 45 may be mounted at an upper portion in the chamber 10 so as to face the electrostatic chuck 20 in the vertical direction Z. The gas supply member 45 may include a plurality of gas spray holes formed therein in order to spray a gas to the interior of the chamber 10. The gas supply member 45 may be formed to have a larger diameter than the electrostatic chuck 20 in a horizontal direction X. The gas supply member 45 may be a shower head including a plurality of gas spray holes formed therein. Further, the gas supply member 45 may be a structure including one or more gas supply nozzles. The gas supply member 45 may be made of a material containing a silicon component or a material containing a metal component.

FIG. 2 is a view showing a coupling structure of an insulating pipe 300 in an electrostatic chuck 20 according to a comparative example. The insulating pipe 300 may include an upper insulating pipe 310 and a lower insulating pipe 320. Referring to FIG. 2, in a state in which a base plate 120 and a ceramic puck 110 are attached to a bonding layer 140, the upper insulating pipe 310 is inserted into a pin hole 160 and is attached to the bonding layer 140. The lower insulating pipe 320 is coupled to a lower side of the upper insulating pipe 310. The lower insulating pipe 320 is attached to the base plate 120 by means of a bonding material 170.

The coupling structure of the insulating pipe 300 shown in FIG. 2 has the following problems. During the plasma processing process, plasma may enter the pin hole 160 and may react with the bonding layer 140. If the bonding layer 140 is exposed to plasma, arcing may occur, and the bonding layer 140 may be deformed. In addition, temperature around the pin hole 160 may suddenly increase due to the reaction of plasma. In addition, the pin hole 160 may be deformed due to a difference in heat strain (degree of thermal expansion) between the ceramic puck 110 and the base plate 120, leading to warpage of the insulating pipe 300. Warpage of the insulating pipe 300 may cause damage to a lift pin 200.

The present disclosure has been made to solve the above problems, and provides an electrostatic chuck 20 capable of preventing the bonding layer 140 from being exposed to plasma and preventing the lift pin 200 from being damaged in spite of a difference in heat strain between the ceramic puck and the base plate, a method of manufacturing the electrostatic chuck 20, and a plasma processing apparatus 1 including the electrostatic chuck 20.

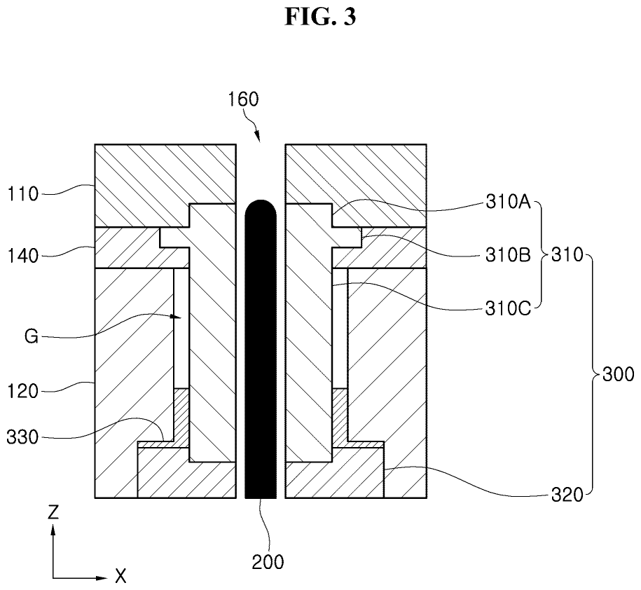

FIG. 3 is a view showing a coupling structure of the insulating pipe 300 in the electrostatic chuck 20 according to the present disclosure. The insulating pipe 300 includes an upper insulating pipe 310 bonded to the ceramic puck 110 and a lower insulating pipe 320 attached to the base plate 120. Referring to FIG. 3, the upper insulating pipe 310 is directly bonded to the ceramic puck 110. According to the present disclosure, because the bonding layer 140 is not exposed to plasma, arcing does not occur, and the bonding layer 140 is not deformed. Further, sudden change in temperature around the pin hole 160 due to the reaction of plasma does not occur. The insulating pipe 300 may be made of a ceramic material (e.g., quartz).

The upper insulating pipe 310 includes a bonding portion 310A brazed to an inner side wall of the pin hole 160 in the ceramic puck 110. In addition, the upper insulating pipe 310 includes a protruding portion 310B protruding outward from a lower side of the bonding portion 310A so as to be attached to the bonding layer 140. In addition, the upper insulating pipe 310 includes a body portion 310C extending downward from a lower side of the protruding portion 310B and having a smaller diameter than the protruding portion 310B. The ceramic puck 110 includes a recess formed in the lower surface thereof around the pin hole 160, and the bonding portion 310A of the upper insulating pipe 310 is bonded to the recess formed in the lower surface of the ceramic puck 110. The upper insulating pipe 310 is inserted into the pin hole 160 in such a manner that the protruding portion 310B having a larger diameter than the bonding portion 310A is attached to the bonding layer 140.

The body portion 310C is attached to the base plate 120 by means of a bonding material 330. The bonding material 330 is formed on an outer side of the upper insulating pipe 310. The bonding material 330 fixes the insulating pipe 300 to the base plate 120. The bonding material 330 is formed on an outer side of the body portion 310C around a coupling portion between the upper insulating pipe 310 and the lower insulating pipe 320. As shown in FIG. 3, the bonding material 330 may be formed on a lower portion of an outer side wall of the body portion 310C and in a recess formed in a lower portion of the base plate 120. The upper insulating plate 310 may be primarily attached to the base plate 120 by means of a portion of the bonding material 330 extending in the vertical direction Z, and the lower insulating pipe 320 may be attached to the upper insulating pipe 310 and the base plate 120 by means of a portion of the bonding material 330 extending in the horizontal direction X.

Referring to FIG. 3, a gap G is formed between the body portion 310C and the base plate 120. The bonding material 330 is attached to a lower portion of an outer side of the body portion 310C of the upper insulating pipe 310, and an empty space is present on the remaining portion of the outer side of the body portion 310C. Thus, a gap G corresponding to the thickness of the bonding material 330 is formed between the body portion 310C and the base plate 120. By virtue of the gap G formed between the upper insulating pipe 310 and the base plate 120, the insulating pipe 300 may not be deformed in spite of a difference in heat strain between the ceramic puck 110 and the base plate 120. Since deformation of the insulating pipe 300 is prevented, damage to the lift pin 200 may be prevented.

The lower insulating pipe 320 may be adhered to the base plate 120 and the upper insulating pipe 310 in a state of being inserted into a recess formed in a lower surface of the base plate 120. As shown in FIG. 3, the lower insulating pipe 320 is attached to the base plate 120 and the upper insulating pipe 310 by means of the bonding material 330. The lower insulating pipe 320 is coupled to the upper insulating pipe 310, thereby blocking the base plate 120 and the bonding layer 140 to prevent the same from being exposed to external plasma.

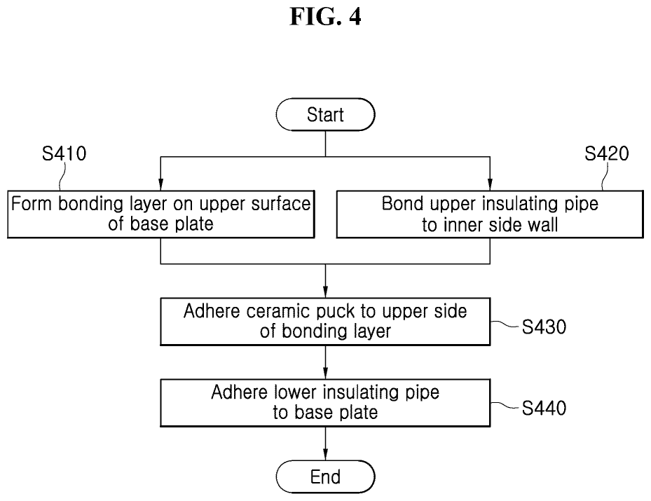

FIG. 4 is a flowchart showing a method of manufacturing the electrostatic chuck 20 according to the present disclosure. The method of manufacturing the electrostatic chuck 20 according to the present disclosure includes a step S410 of forming a bonding layer 140 on an upper surface of a base plate 120, a step S420 of bonding an upper insulating pipe 310 to an inner side wall of a pin hole 160 in a ceramic puck 110 configured to allow a substrate W to be seated thereon, a step S430 of adhering the ceramic puck 110 to an upper side of the bonding layer 140 so that the upper insulating pipe 310 is inserted into the pin hole 160 in the base plate 120, and a step S440 of adhering a lower insulating pipe 320 to a lower side of the upper insulating pipe 310 and the base plate 120.

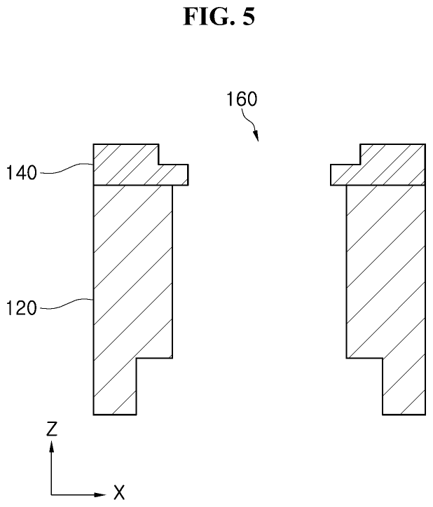

In step S410, as shown in FIG. 5, the base plate 120 is prepared, and the bonding layer 140 is formed on an upper surface of the base plate 120. The bonding layer 140 may be made of a bonding material. The pin hole 160 for ascending and descending of the lift pin 200 is formed in the base plate 120, and a hole corresponding to the pin hole 160 is formed in the bonding layer 140.

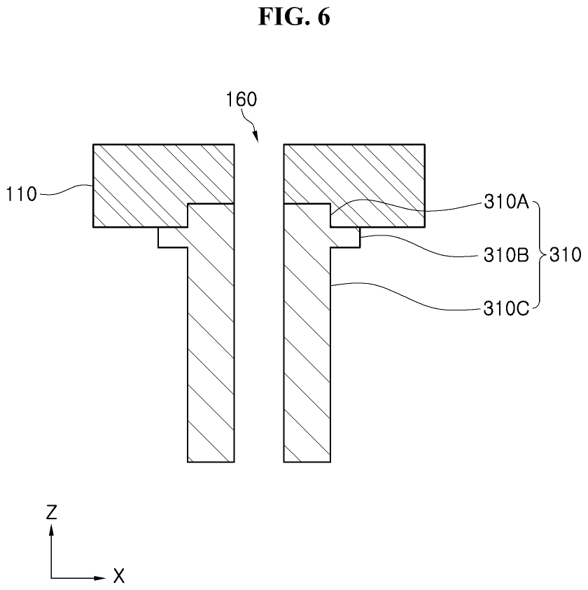

In step S420, as shown in FIG. 6, the ceramic puck 110 is prepared, and the upper insulating pipe 310 is bonded to the pin hole 160 in the ceramic puck 110. The upper insulating pipe 310 includes a bonding portion 310A brazed to an inner side wall of the pin hole 160 in the ceramic puck 110. The upper insulating pipe 310 includes a protruding portion 310B protruding outward from a lower side of the bonding portion 310A so as to be attached to the bonding layer 140. The upper insulating pipe 310 includes a body portion 310C extending downward from a lower side of the protruding portion 310B and having a smaller diameter than the protruding portion 310B.

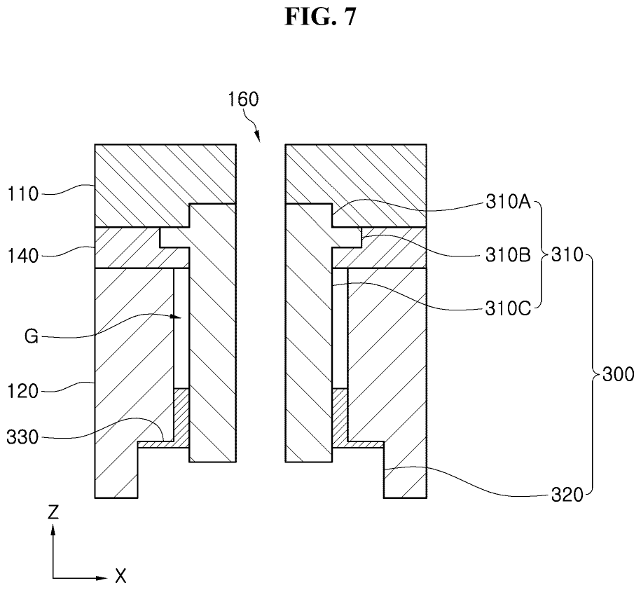

In step S430, as shown in FIG. 7, the ceramic puck 110 is adhered to an upper side of the bonding layer 140 so that the upper insulating pipe 310 is inserted into the pin hole 160 in the base plate 120. That is, the upper insulating pipe 310 is inserted into the pin hole 160 in the base plate 120 simultaneously when the ceramic puck 110 and the base plate 120 are bonded to each other with the bonding layer 140 interposed therebetween. In addition, the body portion 310C of the upper insulating pipe 310 is attached to the base plate 120 by means of a bonding material 330. The bonding material 330 is formed on an outer side of the body portion 310C around a coupling portion between the upper insulating pipe 310 and the lower insulating pipe 320. A gap G is formed between the body portion 310C and the base plate 120.

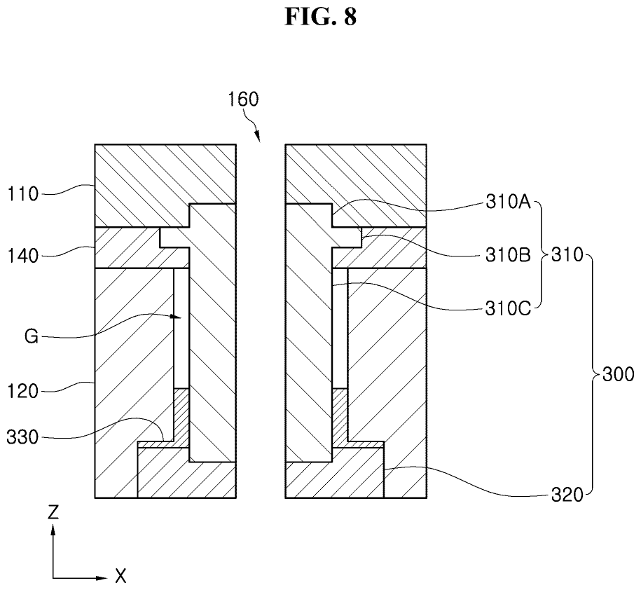

In step S440, as shown in FIG. 8, the lower insulating pipe 320 is attached to a lower side of the upper insulating pipe 310 and the base plate 120. The lower insulating pipe 320 may be coupled to the base plate 120 and the upper insulating pipe 310 by means of the bonding material 330. The lower insulating pipe 320 may be adhered to the base plate 120 and the upper insulating pipe 310 in a state of being inserted into a recess formed in the base plate 120.

As is apparent from the above description, according to the present disclosure, since a bonding layer is not exposed by an insulating pipe including an upper insulating pipe bonded to a ceramic puck and a lower insulating pipe bonded to a base plate, deformation of the bonding layer may be prevented. Further, the insulating pipe may not be warped in spite of a difference in heat strain between the ceramic puck and the base plate, and thus damage to a lift pin may be prevented.

Although the preferred embodiments of the present disclosure have been disclosed for illustrative purposes, those skilled in the art will appreciate that various modifications, additions and substitutions are possible, without departing from the scope and spirit of the disclosure.

The scope of the present disclosure should be defined only by the accompanying claims, and all technical ideas within the scope of equivalents to the claims should be construed as falling within the scope of the disclosure.

What is claimed is:

1. An electrostatic chuck configured to support a substrate and to receive a lift pin so that the lift pin is ascendable and descendable therein, the electrostatic chuck comprising:
at least one pin hole to allow the lift pin to vertically ascend and descend along the at least one pin hole;
a ceramic puck configured to allow the substrate to be seated thereon;
a base plate configured to support the ceramic puck;
a bonding layer configured to bond the ceramic puck to the base plate; and
an insulating pipe mounted on an inner side wall of the at least one pin hole in the ceramic puck,
wherein the at least one pin hole vertically penetrates the ceramic puck, the base plate, and the bonding layer, and
wherein the insulating pipe comprises:
an upper insulating pipe bonded to the ceramic puck; and
a lower insulating pipe adhered to the base plate.

2. The electrostatic chuck according to claim 1, wherein the upper insulating pipe comprises a bonding portion brazed to the inner side wall of the at least one pin hole in the ceramic puck.

3. The electrostatic chuck according to claim 2, wherein the upper insulating pipe comprises a protruding portion protruding outward from a lower side of the bonding portion so as to be attached to the bonding layer.

4. The electrostatic chuck according to claim 3, wherein the upper insulating pipe comprises a body portion extending downward from a lower side of the protruding portion and having a smaller diameter than the protruding portion.

5. The electrostatic chuck according to claim 4, wherein the body portion is attached to the base plate by means of a bonding material.

6. The electrostatic chuck according to claim 5, wherein the bonding material is formed on an outer side of the body portion around a coupling portion between the upper insulating pipe and the lower insulating pipe.

7. The electrostatic chuck according to claim 4, wherein the body portion and the base plate are disposed with a gap therebetween.

8. The electrostatic chuck according to claim 1, wherein the lower insulating pipe is adhered to the base plate and the upper insulating pipe in a state of being inserted into a recess formed in the base plate.

9. A method of manufacturing an electrostatic chuck configured to support a substrate and to receive a lift pin so that the lift pin is ascendable and descendable therein and comprising at least one pin hole formed vertically therethrough to allow the lift pin to ascend and descend along the at least one pin hole, the method comprising:
forming a bonding layer on an upper surface of a base plate;
bonding an upper insulating pipe to an inner side wall of the at least one pin hole in a ceramic puck configured to allow the substrate to be seated thereon;
adhering the ceramic puck to an upper side of the bonding layer so that the upper insulating pipe is inserted into the at least one pin hole in the base plate; and
adhering a lower insulating pipe to a lower side of the upper insulating pipe and the base plate.

10. The method according to claim 9, wherein the upper insulating pipe comprises a bonding portion brazed to the inner side wall of the at least one pin hole in the ceramic puck.

11. The method according to claim 10, wherein the upper insulating pipe comprises a protruding portion protruding outward from a lower side of the bonding portion so as to be attached to the bonding layer.

12. The method according to claim 11, wherein the upper insulating pipe comprises a body portion extending downward from a lower side of the protruding portion and having a smaller diameter than the protruding portion.

13. The method according to claim 12, wherein the body portion is attached to the base plate by means of a bonding material.

14. The method according to claim 13, wherein the bonding material is formed on an outer side of the body portion around a coupling portion between the upper insulating pipe and the lower insulating pipe.

15. The method according to claim 12, wherein the body portion and the base plate are disposed with a gap therebetween.

16. The method according to claim 9, wherein the lower insulating pipe is adhered to the base plate and the upper insulating pipe in a state of being inserted into a recess formed in the base plate.

17. A plasma processing apparatus comprising:
a chamber comprising a plasma processing space for a substrate defined therein;
an electrostatic chuck configured to support the substrate and to receive a lift pin so that the lift pin is ascendable and descendable therein;
an upper electrode configured to generate plasma in the plasma processing space;
a window configured to isolate the upper electrode from the plasma processing space;
a power supply configured to supply power to the upper electrode;
a gas supply member configured to supply a process gas to the plasma processing space; and
a gas source configured to supply the process gas to the gas supply member,
wherein the electrostatic chuck comprises:
at least one pin hole to allow the lift pin to vertically ascend and descend along the at least one pin hole;
a ceramic puck configured to allow the substrate to be seated thereon;
a base plate configured to support the ceramic puck;
a bonding layer configured to bond the ceramic puck to the base plate; and
an insulating pipe mounted on an inner side wall of the at least one pin hole in the ceramic puck,
wherein the at least one pin hole vertically penetrates the ceramic puck, the base plate, and the bonding layer, and
wherein the insulating pipe comprises:
an upper insulating pipe bonded to the ceramic puck; and
a lower insulating pipe adhered to the base plate, and
wherein the upper insulating pipe comprises:
a bonding portion brazed to the inner side wall of the at least one pin hole in the ceramic puck;
a protruding portion protruding outward from a lower side of the bonding portion so as to be attached to the bonding layer; and
a body portion extending downward from a lower side of the protruding portion and having a smaller diameter than the protruding portion.

18. The plasma processing apparatus according to claim 17, wherein the body portion is attached to the base plate by means of a bonding material, and
wherein the bonding material is formed on an outer side of the body portion around a coupling portion between the upper insulating pipe and the lower insulating pipe.

19. The plasma processing apparatus according to claim 17, wherein the body portion and the base plate are disposed with a gap therebetween.

20. The plasma processing apparatus according to claim 17, wherein the lower insulating pipe is adhered to the base plate and the upper insulating pipe in a state of being inserted into a recess formed in the base plate.
